(19) United States
(12) Patent Application Publication
(10) Pub. No.: US 2025/0081354 A1
(43) Pub. Date: Mar. 6, 2025

(54) ELECTRONIC DEVICE AND METHOD OF MANUFACTURING THE SAME

(71) Applicant: InnoLux Corporation, Miao-Li County (TW)

(72) Inventors: Cheng-Chi WANG, Miao-Li County (TW); Tzu-Yen CHIU, Miao-Li County (TW); I-Chang LIANG, Miao-Li County (TW); Chen-Fang HSIAO, Miao-Li County (TW); Jui-Jen YUEH, Miao-Li County (TW)

(21) Appl. No.: 18/782,574

(22) Filed: Jul. 24, 2024

Related U.S. Application Data
(60) Provisional application No. 63/535,812, filed on Aug. 31, 2023.

(30) Foreign Application Priority Data
May 23, 2024 (CN) 202410645257.6

(51) Int. Cl. H05K 3/00; H05K 1/11; H05K 1/18; H05K 3/30

(52) U.S. Cl. CPC H05K 3/0026; H05K 1/115; H05K 1/185; H05K 3/306; H05K 2201/09509; H05K 2203/107

(57) ABSTRACT

A method of manufacturing an electronic device includes providing a substrate with a predetermined first-hole region, a first surface, and a second surface. The second surface is opposite the first surface. The method includes laser processing the predetermined first-hole region from the first surface to form a first laser track and laser processing the predetermined first-hole region from the first surface to form a second laser track. The first laser track does not overlap the second laser track. The method further includes etching the predetermined first-hole region to form a first-hole.

### CROSS REFERENCE TO RELATED APPLICATIONS

This Application claims priority of China Patent Application No. 202410645257.6, filed on May 23, 2024, and U.S. Patent Application No. 63/535,812, filed on Aug. 31, 2023, the entirety of which is incorporated by reference herein.

### BACKGROUND

### Field of the Invention

The disclosure relates to an electronic device and a method of manufacturing the same, and, in particular, to an electronic device with various shapes holes (e.g., rectangular or polygonal) and a method of manufacturing the same.

### Description of the Related Art

In the manufacture of multilayer circuit structures, circular through via holes are commonly used to electrically connect two conductive layers. However, in some specific applications, holes may be formed with special shapes (e.g., rectangular or polygonal). Accordingly, the process for forming holes with special shapes (e.g., rectangular or polygonal) requires further improvements.

### SUMMARY

An embodiment of the disclosure provides a method of manufacturing an electronic device. The method includes providing a substrate having a predetermined first hole region, a first surface, and a second surface opposite to the first surface, laser processing the predetermined first hole region from the first surface to form a first laser track, and laser processing the predetermined first hole region from the first surface to form a second laser track. The first laser track does not overlap the second laser track. The method further includes etching the predetermined first hole region to form a first hole.

Another embodiment of the disclosure provides an electronic device. The electronic device includes a substrate, an electronic component disposed in the first hole, a connection structure disposed in the second hole, and a first conductive layer disposed on the first surface of the substrate. The substrate has a first hole and a second hole. The electronic component is electrically connected to the connection structure via the first conductive layer. A top view profile of the first hole has a different shape from a top view profile of the second hole. The top view profile of the first hole comprises a plurality of straight sides, with adjacent straight sides connected by an arc side.

### BRIEF DESCRIPTION OF THE DRAWINGS

Aspects of the disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1A-1R are cross-sectional views of various stages of manufacturing an electronic device, in accordance with some embodiments.

FIG. 2A is a top view of a laser track pattern of a predetermined first hole region, in accordance with some embodiments. FIG. 2A-1 is a magnified view of the gap in FIG. 2A. FIGS. 2B-2D are top views of a laser track pattern of a predetermined first hole region, in accordance with some other embodiments.

FIG. 3 is a top view of a laser track pattern of a predetermined second hole region, in accordance with some other embodiments.

FIG. 4A is a top view of various stages of manufacturing the electronic device, in accordance with some embodiments.

FIG. 4B is a top view of a first hole, in accordance with some embodiments. FIG. 4B-1 is a magnified view of the first hole in FIG. 4B.

FIG. 4C is top view of a second hole, in accordance with some embodiments.

FIG. 5 is a magnified view of the second hole of the electronic device in FIG. 1C, in accordance with some embodiments.

FIG. 6 is a magnified view of the connection structure of the electronic device in FIG. 1R, in accordance with some embodiments.

### DETAILED DESCRIPTION

The following specification lists various embodiments to introduce the basic concept of the disclosure and are not intended to limit its content. The actual scope of the disclosure should be defined according to the claims. The following will refer in detail to the exemplary embodiments of the disclosure herein, examples of which are illustrated in the accompanying drawings. Wherever possible, the same reference numbers are used in the drawings and the specification to designate the same or similar parts.

The directional terms mentioned herein, such as “above”, “below”, “front”, “back”, “left”, “right”, and the like, refer only to the directions in the accompanying drawings. Therefore, the directional terms are used for describing instead of limiting the disclosure. In the drawings, each drawing illustrates the general characteristics of a method, a structure, and/or material used in a specific embodiment. However, these drawings should not be interpreted as defining or limiting the scope or nature covered by the embodiments. For example, the relative sizes, thicknesses, and positions of various layers, regions, and/or structures may be reduced or enlarged for clarity.

When one structure (or layer, component, substrate) in the disclosure is described as being located on/above another structure (or layer, component, substrate), it may mean that the two structures are adjacent and directly connected. Alternatively, it may mean that the two structures are adjacent but not directly connected, with indirect connection means that there is at least one intermediate structure (or intermediate layer, intermediate component, intermediate substrate, intermediate spacing) between the two structures. The lower surface of one structure is adjacent or directly connected to the upper surface of the intermediate structure, while the upper surface of the another structure is adjacent or directly connected to the lower surface of the intermediate structure, and the intermediate structure may be formed by a single-layer or multi-layer physical structure or non-physical structure without limitation. In the disclosure, when a certain structure is disposed “on” another structure, it may mean that the certain structure is “directly” on the other structure, or that a certain structure is “indirectly” on the other structure. That is, at least one structure is further sandwiched between the certain structure and the other structure.

The disclosure may be understood with reference to the following detailed specification together with the accompanying drawings. It should be noted that, for ease of understanding by readers and clarity of the drawings, a plurality of drawings in the disclosure merely show a part of an electronic device, and specific elements in the drawings are not drawn to scale. In addition, the number and size of elements in the drawings only serve for exemplifying instead of limiting the scope of the disclosure.

Throughout the disclosure, certain terms are used to refer to specific elements in the specification and the claims. Those skilled in the art should understand that electronic device manufacturers may refer to the same components by different names. The specification does not intend to distinguish between components that have the same function but different names.

In following description and claims, terms such as “include”, “comprise”, and “have” are open-ended terms and should thus be interpreted as “including, but not limited to”.

In addition, in this specification, relative expressions may be used. For example, “lower,” “bottom,” “higher,” or “top” are used to describe the position of one element relative to another. It should be noted that if a device is flipped upside down, an element that is “lower” will become an element that is “higher”.

In some embodiments of the disclosure, terms related to bonding and connection such as “connection,” “interconnection,” etc., unless specifically defined, may indicate the case where two structures are in direct contact or where two structures are not in direct contact and other structures are disposed in between. Moreover, such terms related to bonding and connection may also encompass the case where two structures are both movable or where two structures are both fixed. In addition, the term “electrical connection” encompasses the means by which energy is transferred between two structures through direct or indirect electrical connections, or between two separate structures through mutual induction.

It should be understood that when an element or film layer is referred to as being “on” or “connected to” another element or film layer, the element or film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. It should be understood that when an element or film layer is referred to as being “electrically connected to” another element or film layer, the element or film layer may be directly electrically connected to the another element or film layer, or it may be electrically connected to the another element or film layer via intervening conductive elements.

The terms “about,” “equal to,” “equivalent” or “same,” “substantially” or “roughly” are generally interpreted as being within 20% of a given value or range, or interpreted as within 10%, 5%, 3%, 2%, 1%, or 0.5% of a value or range.

Furthermore, any two values or directions used for comparison may have certain errors. If the first value is equal to the second value, it implies that there may be an error of about 10% between the first value and the second value. If the first direction is perpendicular or “substantially” perpendicular to the second direction, the angle between the first direction and the second direction may be between 80° and 100°. If the first direction is parallel or “substantially” parallel to the second direction, the angle between the first direction and the second direction may be between 0° and 10°.

The ordinal numbers used in the specification and the claims, such as “first” or “second,” are used to modify elements, and the ordinal numbers do not imply or represent that the element(s) have any previous ordinal numbers, nor do they represent the order of a certain element and another element or the order of a manufacturing method. The use of the ordinal numbers is only used to clearly distinguish between an element with a certain name and another element with the same name. The claims and the specification may not use the same terms, whereby a first component in the specification may be a second component in the claims.

In the disclosure, the terms “the given range is from a first value to a second value” and “the given range is within the range from a first value to a second value” both mean that the given range includes the first value, the second value, and other values in between.

In some embodiments of the disclosure, optical microscopy (OM), scanning electron microscope (SEM), thin film thickness profiler (α-step), ellipsometer, or other suitable manners may be used to measure a depth, a thickness, a width, or a height of each element or measure a distance or a spacing between elements. According to some embodiments, SEM may be used to obtain a cross-sectional structural image including an element to be measured, and to measure a depth, a thickness, a width, or a height of each element or to measure a distance or a spacing between elements.

The electronic device of the disclosure may include electronic components. The electronic components may include passive components, active components, or combinations thereof, such as connectors, capacitors, resistors, inductors, varactor diodes, variable capacitors, filters, diodes, transistors, sensors, microelectromechanical system (MEMS) components, liquid crystal chips, etc., but the disclosure is not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or combinations thereof, but the disclosure is not limited thereto. The sensing device may include, for example, capacitive sensors, optical sensors, electromagnetic sensors, fingerprint sensors (FPS), touch sensors, antennas, or pen sensors, etc., but are not limited to thereto. Electronic components may include dies or LED dies, which may be a die made of silicon (Si), gallium arsenide (GaAs), gallium nitride (GaN), silicon carbide (SiC), sapphire or a glass substrate, but the disclosure is not limited thereto. In another embodiment, the above-mentioned die may include a semiconductor packaging component, such as a ball grid array (BGA) packaging component, a chip size package (CSP) component, a flip-chip, or a 2.5D/3-dimensional (2.5D/3D) semiconductor packaging component, but the disclosure is not limited thereto. In another embodiment, the die may be any flip-chip bonding component, such as integrated circuits (ICs), transistors, controlled silicon rectifiers, valves, thin film transistors, capacitors, inductors, variable capacitors, filters, resistors, diodes, microelectromechanical system (MEMS) components, liquid crystal chips, etc., but the disclosure is not limited thereto. In addition, the die may include, for example, a diode or a semiconductor die, but the disclosure is not limited thereto. The die may be a known good die (KGD), which may include various electronic components, such as (but not limited to) lines, transistors, circuit boards, etc. Adjacent dies may have different functions, such as integrated circuits, radio frequency integrated circuits (RFICs), and dynamic random access memories (D-RAMs), but the disclosure is not limited thereto.

The following will refer in detail to the exemplary embodiments of the disclosure herein, examples of which are illustrated in the accompanying drawings. Wherever possible, the same reference numbers are used in the drawings and the specification to designate the same or similar parts. The electronic devices may include artificial intelligence (AI) server devices, data center server devices, edge computing devices, Internet of Things (IoT) devices, satellite communication devices, in-car entertainment systems, battery management devices, imaging devices, bonding devices, display devices, backlight devices, antenna devices, splicing devices, touch display devices, curved display devices, or free shape displays, among others, but the disclosure is not limited thereto. The electronic devices may include liquid crystal, light emitting diodes, fluorescence, phosphors, other suitable display media or combinations thereof, but the disclosure is not limited thereto. The display devices may be non-self-luminous display devices or self-luminous display devices. The antennas may be liquid crystal type antennas or non-liquid crystal type antennas. The sensing devices may be sensing devices for sensing capacitance, light, heat, or ultrasonic, but the disclosure is not limited thereto. The splicing devices may be, for example, display splicing devices or radio frequency splicing devices, but the disclosure is not limited thereto. The electronic devices of the disclosure can be applied to power modules, semiconductor packaging devices, display devices, lighting devices, backlight devices, antenna devices, sensing devices, or splicing devices, among others, but the disclosure is not limited thereto. The electronic device may include a bendable or flexible electronic device. The shape of the electronic device can be rectangular, circular, polygonal, have curved edges, or any other suitable shape. It should be noted that the following embodiments can replace, recombine, and combine features in several different embodiments to complete other embodiments without departing from the spirit of the disclosure. The features between the various embodiments can be combined and used arbitrarily as long as they do not violate or conflict the spirit of the disclosure.

Unless defined otherwise, all terms (including technical and scientific terms) used herein have the same meaning as commonly understood by one of ordinary skill in the art to which this disclosure belongs. It should be appreciated that, in each case, the term, as defined in a commonly used dictionary, should be interpreted as having a meaning that conforms to the relative skills of the disclosure and the background or the context of the disclosure, and should not be interpreted in an idealized or overly formal manner unless defined as such in the disclosure. One aspect of the disclosure is to provide an electronic device including a novel circuit structure.

In some specific applications (e.g., glass connectors or other applications, etc.), holes with special shapes (e.g., rectangular or polygonal) may be formed in the substrate. However, the process currently used for forming holes with special shapes requires further improvements.

The disclosure provides an electronic device with holes of various shapes (e.g., rectangular or polygonal) and a method of manufacturing the same. By employing the laser track pattern design rule of the disclosure during the laser process, holes with special shapes (e.g., rectangular, polygonal, etc.) can be formed in the substrate, in accordance with embodiments. Through the dimension design of the laser track pattern, the profile of the subsequently formed holes at the corners can be made more symmetrical. Furthermore, by designing the shape of the laser track pattern, the required etching time in the subsequent etching process can be reduced or relatively vertical sidewalls of holes can be obtained.

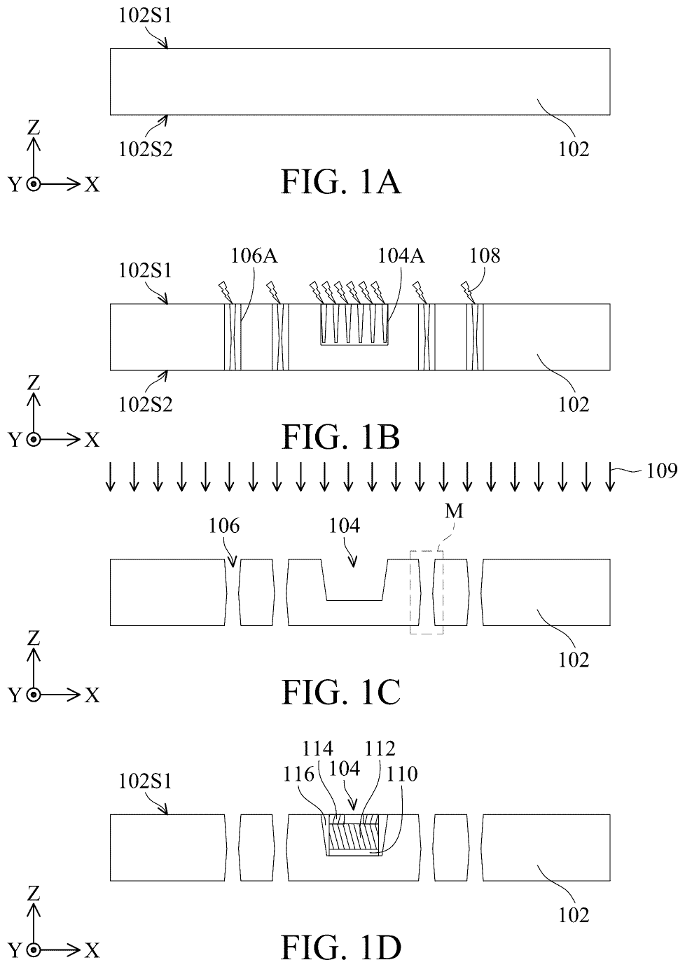

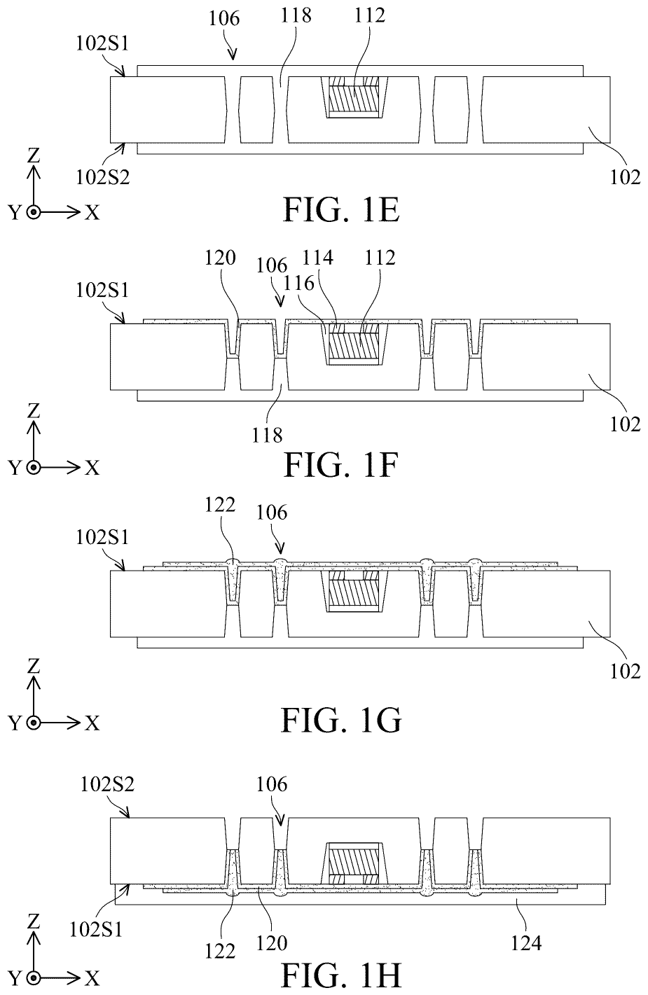

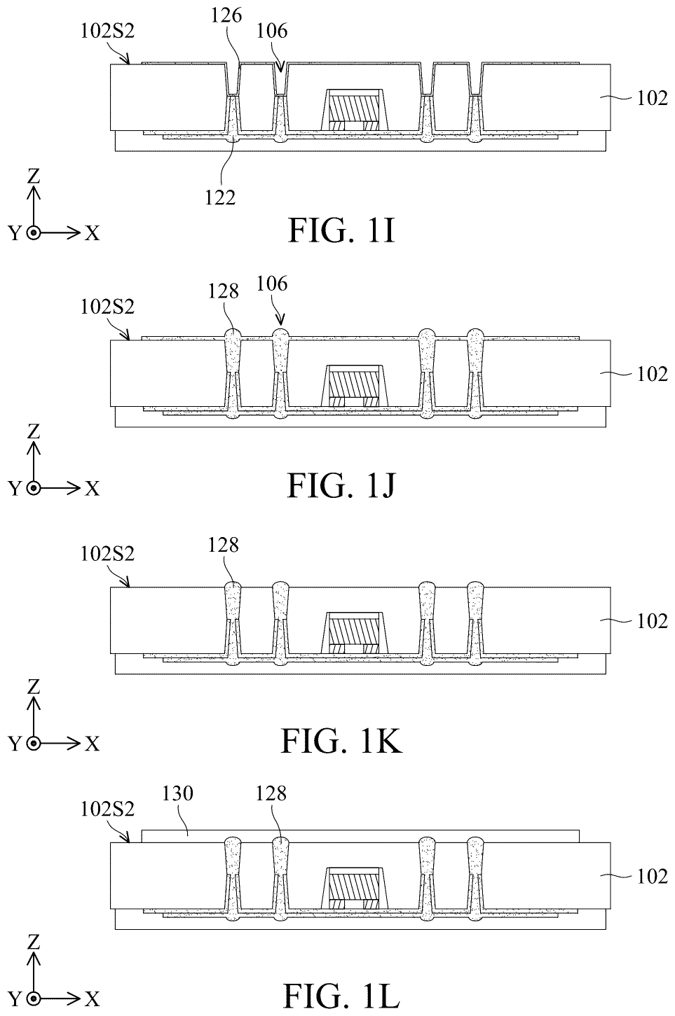

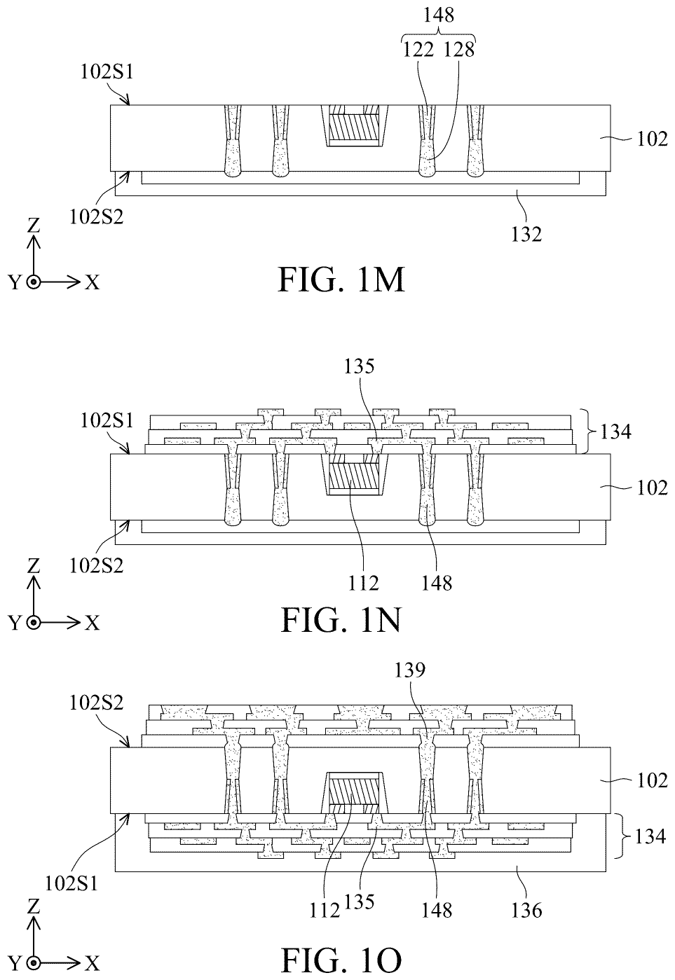

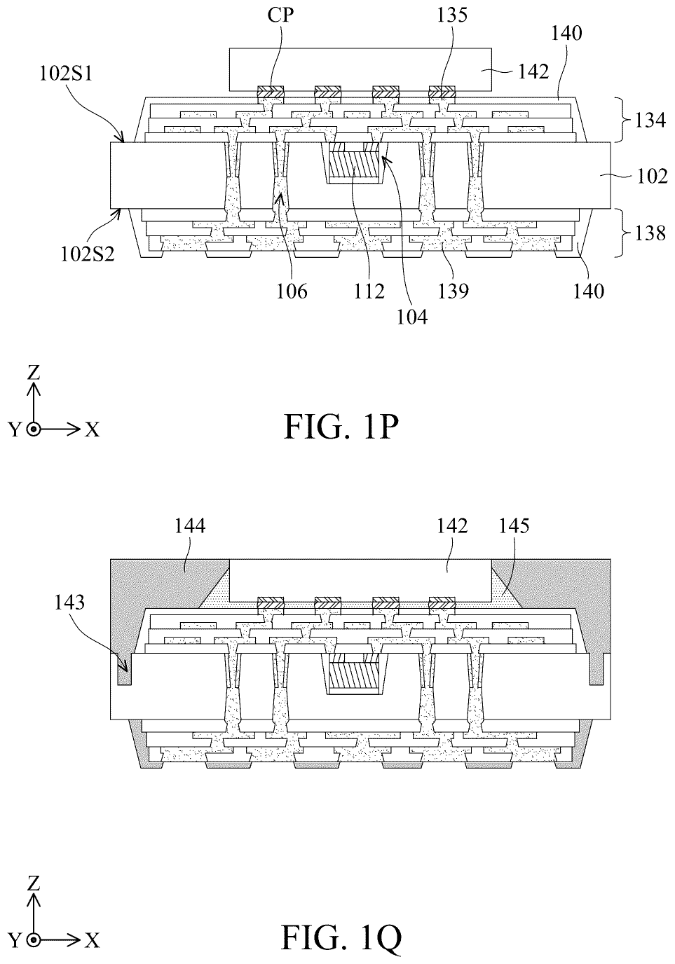

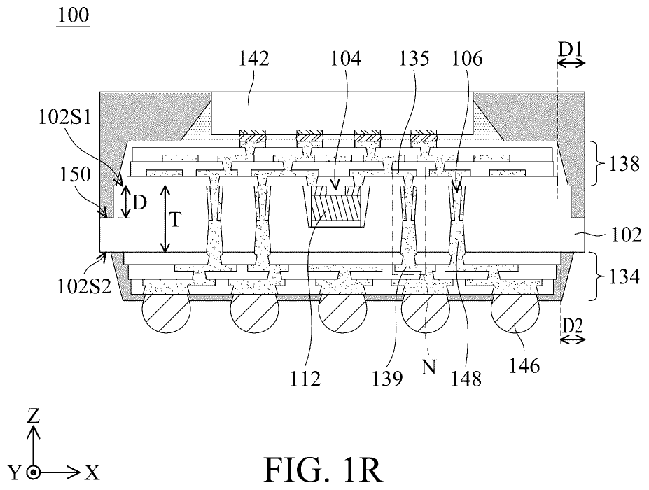

FIGS. 1A-1R are cross-sectional views of various stages of manufacturing an electronic device 100, in accordance with some embodiments. It should be noted that, for concise explanation, some components of the electronic device 100 may be omitted in the drawings, and only some components are schematically illustrated. Additional features may be added to the electronic device 100 described below, in accordance with some embodiments.

Referring to FIG. 1A, in one embodiment, the substrate 102, having a first surface 102S1 and a second surface 102S2 opposite to each other, is provided. In some embodiments, the substrate 102 may include a rigid substrate, a flexible substrate or combinations thereof. For example, the material of the substrate 102 may include glass, quartz, sapphire, acrylic resin, polycarbonate (PC), polyimide (PI), polyethylene terephthalate (PET), combinations thereof, or other suitable substrate materials, but the disclosure is not limited thereto.

Referring to FIG. 1B, in one embodiment, the substrate 102 has a predetermined first hole region 104A and/or a predetermined second hole region 106A. The term “hole” used herein may include a through hole or a blind hole, but is not limited thereto. A through hole is a hole that penetrate the substrate, while a blind hole is a hole that do not penetrate the substrate. In the following embodiments, a first hole 104 and a second hole 106 will be exemplified as a blind hole and a through hole, respectively, for illustration purpose, but the disclosure is not limited thereto.

In some embodiments, a laser 108 is applied at least twice to the predetermined first hole region 104A from the first surface 102S1 of the substrate 102. In some embodiments, the laser 108 is applied onto the first surface 102S1 of the substrate 102 to modify the predetermined first hole region 104A so that it can be easily removed by etching.

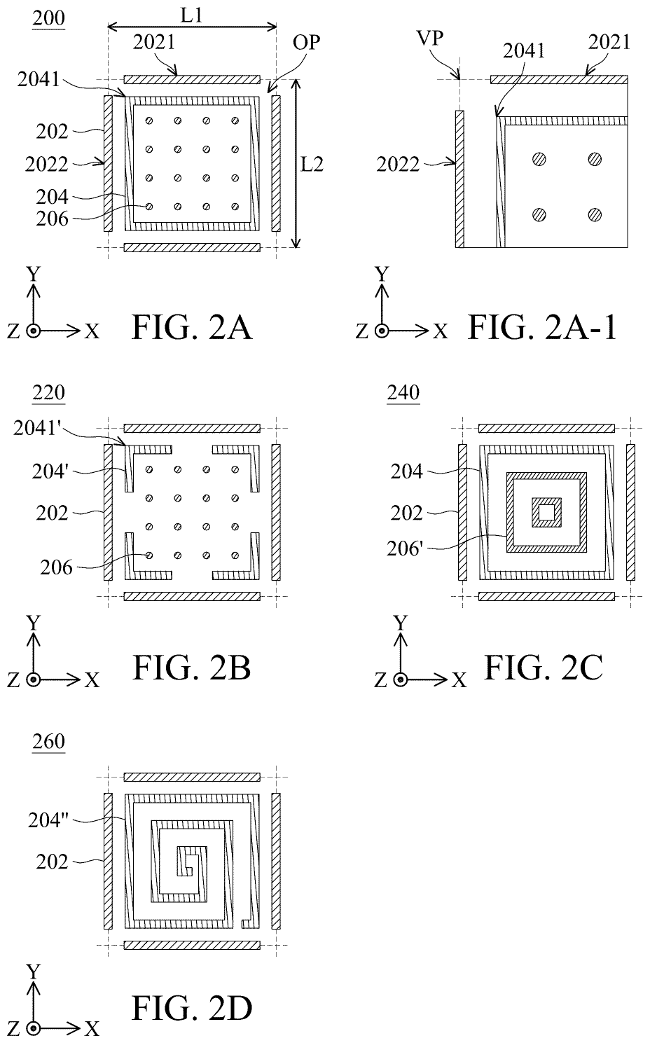

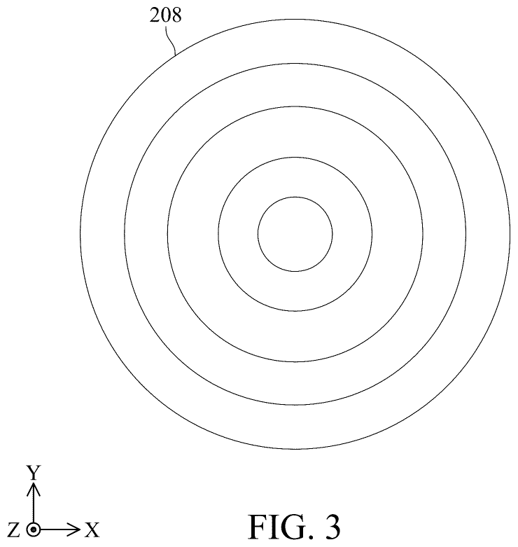

Referring to FIG. 1B in conjunction with FIGS. 2A-2D. FIG. 2A is a top view of a laser track pattern 200 of a predetermined first hole region 104A, in accordance with some embodiments. FIG. 2A-1 is a magnified view of the gap OP in FIG. 2A.

In one embodiment, the laser 108 is applied to the predetermined first hole region 104A from the first surface 102S1 of the substrate 102 to form a first laser track 202, as illustrated in FIG. 1B. In addition, the laser 108 is then applied to the predetermined first hole region 104A from the first surface 102S1 to form a second laser track 204, thereby forming a laser track pattern 200 including the first laser track 202 and the second laser track 204, as illustrated in FIG. 2A. The predetermined first hole region 104A is etched to form a first hole 104, but the disclosure is not limited thereto. In one embodiment, the first laser track 202 may be formed before the second laser track 204. In other embodiments, the second laser track 204 may be formed before the first laser track 202. In one embodiment, the first laser track 202 does not overlap the second laser track 204 when viewed from the top of the substrate (i.e., along the Z-axis or third direction). The term “laser track” refers to the track of the center points of the laser, and only the track of the laser center points is illustrated in the drawing for clarity.

As illustrated in FIG. 2A, in one embodiment, the first laser track 202 surrounds the second laser track 204. In one embodiment, the first laser track 202 has a plurality of straight portions (e.g., a first portion 2021 and a second portion 2022), where adjacent straight portions (e.g., the first portion 2021 and the second portion 2022) are not parallel to each other and spaced apart by a gap OP. The adjacent straight portions are respectively the first portion 2021 and the second portion 2022 perpendicular to the first portion 2021, and the gap OP may between the first portion 2021 and the second portion 2022. It should be noted that although FIG. 2A illustrates that the first laser track 202 includes four straight portions, and their extension lines may intersect to form a rectangle, but the disclosure is not limited thereto. In other embodiments (not shown), the quantity and relative position of the straight portions can be adjusted according to requirements. For example, the first laser track 202 may include five unconnected straight portions, and their extension lines intersect to form a pentagon, or it may include six unconnected straight portions, and their extension lines intersect to form a hexagon.

Still referring to FIG. 2A, in one embodiment, the second laser track 204 has a plurality of portions 2041. It should be noted that although FIG. 2A illustrates that the second laser track 204 includes four portions 2041, and these portions 2041 (including, but not limited to, L-shaped portions) are connected to each other to form a rectangular shape, but the disclosure is not limited thereto. In other embodiments, the profile of the second laser track 204 may correspond to the profile of the first laser track 202, but the disclosure is not limited thereto.

In some embodiments, the laser track pattern 200 further includes a third laser track 206 surrounded by the second laser track 204. Although the third laser track 206 is illustrated as a plurality of dot-shaped portions in FIG. 2A, for example, arranged in an array, but the disclosure is not limited thereto. In other embodiments, the pattern of the third laser track 206 may be formed according to requirements. In other embodiments, the third laser track 206 can also be optionally omitted.

Some other embodiments of the disclosure will be described below with reference to FIGS. 2B-2D. FIGS. 2B-2D are top views of a laser track pattern 220, 240, and 260 of a predetermined first hole region 104A, in accordance with some other embodiments. It should be noted that the features between the various embodiments can be combined and used interchangeably as long as they do not violate or conflict with the spirit of the disclosure. The laser track pattern 220 in FIG. 2B is similar to the laser track pattern 200 in FIG. 2A, except that the second laser track 204′ of the laser track pattern 220 includes unconnected portions 2041′ (such as L-shaped portions) at positions corresponding to the four corners of the first laser track 202, resulting in gaps between adjacent portions 2041′. The laser track pattern 240 in FIG. 2C is similar to the laser track pattern 200 in FIG. 2A, except that the third laser track 206′ is illustrated as a series of sequentially surrounding rings (e.g., a series of sequentially surrounding rectangles, but the disclosure is not limited thereto). The laser track pattern 260 in FIG. 2D is similar to the laser track pattern 200 in FIG. 2A, except that the second laser track 204″ is illustrated as a spiral shape, and the third laser track 206 may optionally absent in this embodiment. In some embodiments, since the laser track pattern 240 and/or the laser track pattern 260 exhibit higher density laser tracks, they can achieve higher etching efficiency (e.g., a shorter etching time) in the subsequent etching process (e.g., the etching process 109 in FIG. 1C) or yield more vertical hole sidewall, but the disclosure is not limited thereto.

Referring to FIG. 2A in conjunction with FIG. 2A-1, in some embodiments, the first laser track 202 spans a maximum width L1 along the first direction X, and a maximum width L2 along the second direction Y. In one embodiment, the adjacent straight portions are respectively the first portion 2021 and the second portion 2022 perpendicular to the first portion 2021, and the gap OP is between the first portion 2021 and the second portion 2022. The extension lines of the first portion 2021 and the second portion 2022 of the straight portions of the first laser track 202 intersect at a virtual point VP, and the virtual point VP is at the first shortest distance d1 from the first portion 2021 and the second shortest distance d2 from the second portion 2022. In some embodiments, at least one of the first shortest distance d1 and the second shortest distance d2 is greater than zero (0). For example, both the first shortest distance d1 and the second shortest distance d2 are greater than zero (d1>0; d2>0), the first shortest distance d1 is greater than zero (d1>0), and the second shortest distance d2 is equal to zero (d2=0), or he first shortest distance d1 is equal to zero (d1=0), and the second shortest distance d2 is greater than zero (d2>0). In some embodiments, the first shortest distance d1 and the second shortest distance d2 satisfy the following equation: 0.8≤d1/d2≤1.2, L1/50≤d1≤L1/10, and L2/50≤d1≤L2/10, but the disclosure is not limited thereto. Alternately, 0.85≤d1/d2≤1.15, L1/40≤d1≤L1/20, and L2/40≤d1≤L2/20, but the disclosure is not limited thereto. When the first shortest distance d1 and the second shortest distance d2 meet the above-mentioned conditions, the corner of the first hole 104 can be closer to a right angle, or the profile can be more symmetrical.

In one embodiment, the second laser track 204 has a plurality of portions 2041, with one of the portions 2041 being adjacent to the gap OP. In one embodiment, the virtual point VP is at a third shortest distance d1 from said portion 2041. The first shortest distance d1, the second shortest distance d2, and the third shortest distance d3 satisfy the following equation:

$$0 \text{.8} \times \sqrt{d {1}^{2} + d {2}^{2}} \leq d 3 \leq 1 \text{.2} \times \sqrt{d {1}^{2} + d {2}^{2}} or \\ 0.85 \times \sqrt{d {1}^{2} + d {2}^{2}} \leq d 3 \leq 1.15 \times \sqrt{d {1}^{2} + d {2}^{2}} .$$

When the third shortest distance d3 meet the above-mentioned conditions, the corner of the subsequently formed first hole 104 can be closer to a right angle.

Referring back to FIG. 1B in conjunction with FIG. 3. FIG. 3 is a top view of a laser track pattern 300 of a predetermined second hole region 106A, in accordance with some other embodiments. In one embodiment, the laser 108 is applied to the predetermined second hole region 106A from the first surface 102S1 of the substrate 102, as illustrated in FIG. 1B. In cases where through holes are to be formed and the substrate 102 is thick, the laser 108 should not be applied on the predetermined second hole region 106A only from the first surface 102S1, but also from the second surface 102S2 (i.e., performing a double-sided laser modification), but the disclosure is not limited thereto.

As illustrated in FIG. 3, the laser track pattern 300 for forming the second hole 106 may include a plurality of circular laser tracks 208 or spiral laser tracks (not shown) surrounding each other, but the disclosure is not limited thereto. As a result, a higher etching efficiency (e.g., a shorter etching time) can be attained in the subsequent etching process (e.g., the etching process 109 in FIG. 1C), or a more vertical hole sidewall can be achieved, but the disclosure is not limited thereto.

Next, referring back to FIG. 1C, in one embodiment, the laser 108 is applied and the etching process 109 is performed on the predetermined first hole region 104A and the predetermined second hole region 106A to form the first hole 104 and the second hole 106, respectively. In some embodiments, the etching process 109 for the predetermined first hole region 104A and the predetermined second hole region 106A may be performed simultaneously, but the disclosure is not limited thereto. In other embodiments, the etching processes 109 for the predetermined first hole region 104A and the predetermined second hole region 106A may be performed separately. In some embodiments, the etching process 109 may be an isotropic etching process, such as a wet etching process, which utilizes an etchant (e.g., a hydrofluoric acid (HF) solution, other suitable etchants, or combinations thereof) to remove regions of the substrate 102 (e.g., the predetermined first hole region 104A and the predetermined second hole region 106A) modified by the laser 108, but the disclosure is not limited thereto.

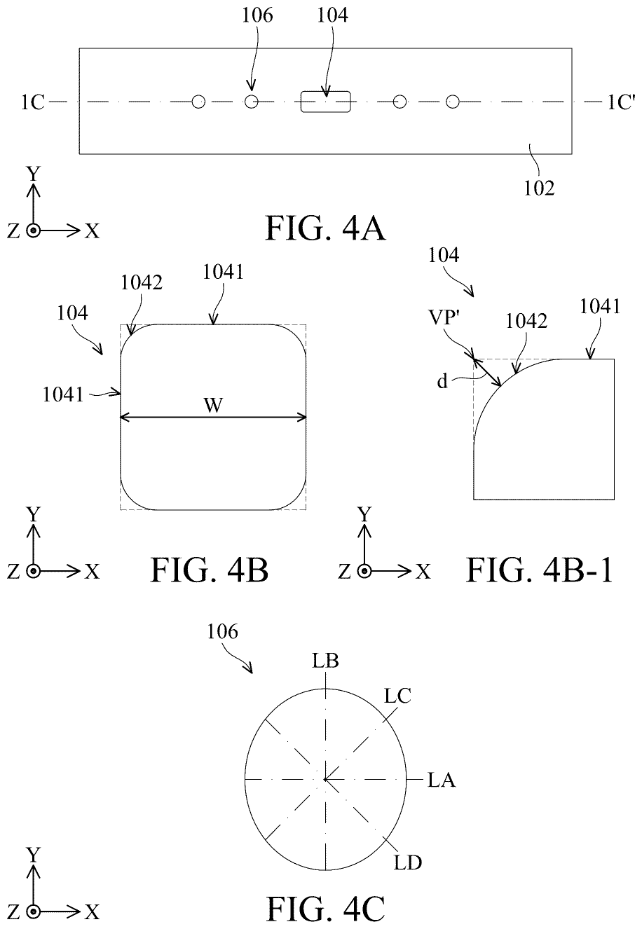

Referring to FIG. 1C in conjunction with FIGS. 4A-4C. FIG. 4A is a top view of various stages of manufacturing the electronic device 100, in accordance with some embodiments. The drawing illustrates an approximately rectangular first hole 104 and a second hole 106 (whose profile may be approximately circular or elliptical, but the disclosure is not limited thereto), but the disclosure is not limited thereto. FIG. 1C is a cross-sectional view taken along line 1C-1C′ in FIG. 4A. FIG. 4B is a top view of a first hole 104, in accordance with some embodiments. FIG. 4B-1 is a magnified view of the first hole 104 in FIG. 4B. FIG. 4C is top view of a second hole 106, in accordance with some embodiments.

Referring to FIG. 4A, in one embodiment, the substrate 102 has a first hole 104 and a second hole 106. The top view profile of the first hole 104 has a different shape from the top view profile of the second hole 106. For example, the top view profile of the first hole 104 may be approximately rectangular, while that of the second hole 106 may be approximately circular, but the disclosure is not limited thereto. In other embodiments, according to design requirements, the shape of the top view profile of the first hole 104 may be rectangular, polygonal, or other suitable shapes, and the shape of the top view profile of the second hole 106 may be circular, elliptical, rectangular, polygonal, or other suitable shapes.

Referring to FIG. 4B, in some embodiments, the top view profile of the first hole 104 includes a plurality of straight sides 1041, and the adjacent straight sides connected by an arc side 1042, but the disclosure is not limited thereto. In other embodiments, as illustrated in FIG. 4B-1, extension lines of the adjacent straight sides 1041 of the top view profile of the first hole 104 intersect at a virtual point VP′, the virtual point VP′ is spaced apart from the arc side 1042 by a shortest distance d. The first hole 104 may have a maximum width w along the first direction X, the shortest distance d and the maximum width w satisfy the following equation: 0<d/w≤0.1 (e.g., 0<d/w≤0.06). When the shortest distance d is small, the corner of the first hole 104 can be closer to a right angle.

As illustrated in FIG. 4C, when the top view profile of the second hole 106 is approximately circular, the ratio between any two of the first diameter LA, the second diameter LB, the third diameter LC and the fourth diameter LD is greater than 92% (e.g., greater than 95%). In some embodiments, the dimensions (including area, length, and width) of the top view profile of the first hole 104 differ from those of the top view profile of the second hole 106, but the disclosure is not limited thereto.

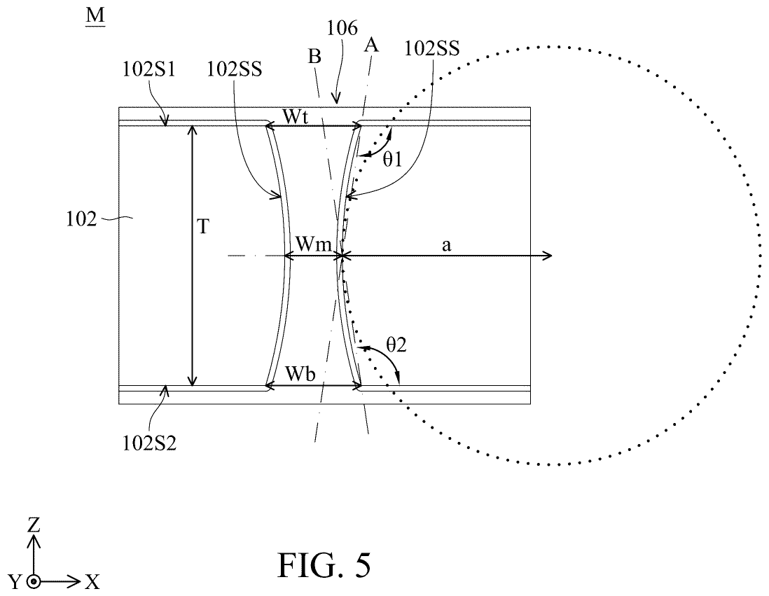

Referring back to FIG. 1C in conjunction with FIG. 5. FIG. 5 is a magnified view of the second hole 106 of the electronic device 100 in FIG. 1C, in accordance with some embodiments.

As illustrated in FIG. 5, in the cross-sectional view of the electronic device 100, the substrate 102 has a thickness T, and the side surface of the second hole 106 is an arc plane with a radius of curvature a, but the disclosure is not limited thereto. The thickness T of the substrate 102 can be determined by averaging the thicknesses of any three locations corresponding to the areas without holes. In other embodiments (not shown), the second hole 106 may have vertical side surfaces that are substantially perpendicular to the first surface 102S1 of the substrate 102. In some embodiments, the concavity degree on the side of the second hole 106 depends on the thickness T of the substrate 102 and/or the process parameters of the etching process 109. When the process parameters of the etching process 109 are fixed, the thickness T and the radius of curvature a satisfy the following equation:

$$T / 2 < a \leq 10 T or T < a \leq 8 T .$$

In some embodiments, the first surface 102S1 and the second surface 102S2 of the substrate 102 each form an included angle θ1 and an included angle θ2, respectively, with the side 102SS of the substrate 102 corresponding to the second hole 106. The included angle θ1 and/or the included angle θ2 is greater than or equal to 90° (θ1>90° and/or θ2>90°). In some embodiments, a virtual line C may be defined at approximately half the thickness T of the substrate 102, and the virtual line C is approximately parallel to the first surface 102S1 of the substrate 102. The side 102SS of the substrate 102 corresponding to the second hole 106 intersects with the virtual line C at a certain point. A virtual line A can be defined between the point and the top of the side 102SS (i.e., the point where the second hole 106 corresponds to the first surface 102S1). The included angle θ1 is defined as the angle between the first surface 102S1 of the substrate 102 and the virtual line A. Similarly, the side 102SS of the substrate 102 corresponding to the second holes 106 intersects with the virtual line C at a certain point. A virtual line B can be defined between the point and the bottom of the side 102SS (i.e., the point where the second hole 106 corresponds to the second surface 102S2). The included angle θ2 is defined as the angle between the second surface 102S2 of the substrate 102 and the virtual line B.

In some embodiments, as illustrated in FIG. 5, the second hole 106 has the width Wt at the first surface 102S1, the width Wb at the second surface 102S2, and the width Wm between the first surface 102S1 and the second surface 102S2, along the first direction X. In some embodiments, the cross-section of the second hole 106 is generally tapered, with the width Wt being, for example, greater than the width Wm, and the width Wm being greater than the width Wb (Wt>Wm>Wb, but the disclosure is not limited thereto), but the disclosure is not limited thereto. In some embodiments, the cross-section of the second hole 106 is generally tapered, the width Wt is smaller than the width Wm, and the width Wm is smaller than the width Wb (Wt<Wm<Wb, but the disclosure is not limited thereto). In some embodiments, the side of the second hole 106 is a concave arc surface (i.e., narrower approximately in the middle of the hole), both the width Wt and the width Wb are greater than the width Wm (Wt>Wm and Wb>Wm), and the width Wt and the width Wb satisfy the following equation: 0.8≤Wb/Wt≤1.2 or 0.85≤Wb/Wt≤1.15. Through the above design, the hole becomes relatively symmetrical, or it reduces the impact of the subsequent connection of the conductive layer disposed on the first surface 102S1 and the second surface 102S2 of the substrate 102 due to one side of the hole having too small width.

Referring back to FIG. 1D, in one embodiment, an electronic component 112 is disposed in the first hole 104. In some embodiments, the electronic device 100 further includes an attachment 110 disposed under the electronic component 112 and a filling layer 116 disposed in the first hole 104, covering the electronic component 112, but the disclosure is not limited thereto.

In some embodiments, the electronic component 112 may include various types of passive components and active components, such as connectors, capacitors, resistors, inductors, varactor diodes, variable capacitors, filters, diodes, transistors, sensors, microelectromechanical system (MEMS) components, liquid crystal chips, etc., but the disclosure is not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or combinations thereof, but the disclosure is not limited thereto. The sensing device may include, for example, capacitive sensors, optical sensors, electromagnetic sensors, fingerprint sensors (FPS), etc., but are not limited to thereto. The electronic component 112 may include dies or LED dies, which may be a die made of silicon (Si), gallium arsenide (GaAs), gallium nitride (GaN), silicon carbide (SiC), sapphire or a glass substrate, but the disclosure is not limited thereto.

In some embodiments, the electronic component 112 can be disposed or secured in the first hole 104 using the attachment 110. The attachment 110 may include double-sided tape, cured glue, or other suitable attachments, but the disclosure is not limited thereto. In some embodiments, the electronic component 112 includes a conductive pad layer 114, and the electronic component 112 is electrically connected to the conductive pad layer 114. The material of the conductive pad layer 114 may include nickel (Ni), copper (Cu), nickel alloy, copper alloy, other suitable materials or combinations thereof, but the disclosure is not limited thereto.

In some embodiments, the filling layer 116 can fill at least a portion of the first hole 104. The filling layer 116 serves to protect the electronic component 112 and/or the conductive pad layer 114, enhancing the reliability of the electronic device 100, but the disclosure is not limited thereto. The filling layer 116 may include materials such as liquid epoxy resin, deformable gel, silicone rubber or similar materials, but the disclosure is not limited thereto. In some embodiments, the formation of the filling layer 116 includes disposing filling material layer in the first hole 104 to cover the electronic component 112 and/or the conductive pad layer 114. Subsequently, a planarization process is selectively performed to remove the excess filling material layer and expose a portion of the conductive pad layer 114, thereby forming the filling layer 116, but the disclosure is not limited thereto.

In one embodiment, a connection structure 148 is formed or disposed in the second hole 106 subsequent to the planarization process, as illustrated in FIGS. 1E-1M.

Referring to FIG. 1E, in some embodiments, the filling layer 118 is filled into the second hole 106, covering at least a portion of the first surface 102S1 and/or the second surface 102S2 of the substrate 102, but the disclosure is not limited thereto. The material of the filling layer 118 may include epoxy resin, polyimide, other suitable resin materials, or combinations thereof, but the disclosure is not limited thereto.

Referring to FIGS. 1F-1G, in some embodiments, a portion of the filling layer 118 is removed to expose the first surface 102S1 of the substrate 102 and/or a portion of the sidewall of the second hole 106, as illustrated in FIG. 1F. In some embodiments, after the above-mentioned removal process, a first seed layer 120 is formed (deposited) from the first surface 102S1 of the substrate 102, as illustrated in FIG. 1F. The first seed layer 120 may be disposed on and/or in contact with the first surface 102S1 of the substrate 102, the conductive pad layer 114, the filling layer 118 and/or a portion of the sidewall of the second hole 106. Subsequently, as illustrated in FIG. 1G, in some embodiments, a first conductive structure 122 is formed (deposited) on the first surface 102S1 of the substrate 102. In some embodiments, the materials used for the first seed layer 120 and the first conductive structure 122 may include gold (Au), silver (Ag), copper (Cu), palladium (Pd), platinum (Pt), ruthenium (Ru), aluminum (Al), cobalt (Co), nickel (Ni), titanium (Ti), molybdenum (Mo), manganese (Mn), zinc (Zn), an alloy thereof, and combinations thereof, but the disclosure is not limited thereto. In some embodiments, the first seed layer 120 may be deposited using physical vapor deposition (PVD) process, chemical vapor deposition (CVD), atomic layer deposition (ALD), other suitable processes, or combinations thereof, but the disclosure is not limited thereto. In some embodiments, the first conductive structure 122 may be deposited using an electroplating process, other suitable methods, or combinations thereof, but the disclosure is not limited thereto.

Referring to FIG. 1H, in some embodiments, after the formation of a first protective layer 124 on the first surface 102S1 of the substrate 102, for example, the substrate 102 may be flipped upside down (i.e., the second surface 102S2 facing upward). The first protective layer 124 may serve as a temporary protective film (TPF). In some embodiments, the first protective layer 124 may be removed, for example, in a subsequent manufacturing step of the electronic device 100 (as illustrated in the subsequent FIG. 1M), but the disclosure is not limited thereto. In some embodiments, the first protective layer 124 may include a single layer of material or a composite material. When the first protective layer 124 is a composite material, it may include a combination of film layers, glue materials, and/or other suitable materials, but the disclosure is not limited thereto. The above-mentioned film layers includes, for example, polyethylene terephthalate (PET), polyimide (PI), other suitable materials and/or combinations thereof, but the disclosure is not limited thereto. The above-mentioned glue materials include, for example, pressure-sensitive adhesives, acrylic adhesives, epoxy resins, silicone, other suitable materials and/or combinations thereof, but the disclosure is not limited thereto.

Next, in some embodiments, as illustrated in FIG. 1H, the filling layer 118 on the opposite side is removed to expose the second surface 102S2 of the substrate 102, another portion of the sidewall of the second hole 106, and/or a portion of the first seed layer 120 (e.g., the part of the first seed layer 120 filled in the second hole 106). In some embodiments, the exposed first seed layer 120 in the second hole 106 is removed via an etching process, but the disclosure is not limited thereto.

Referring to FIGS. 1I-1J, in some embodiments, a second seed layer 126 is formed (deposited) from the second surface 102S2 of the substrate 102, as illustrated in FIG. 11. The second seed layer 126 may be disposed on the second surface 102S2 of the substrate 102, the first conductive structure 122, and/or another portion of the sidewall of the second hole 106. Subsequently, in some embodiments, a second conductive structure 128 is deposited (or disposed) from the second surface 102S2 of the substrate 102, as illustrated in FIG. 1J. In some embodiments, the materials and formation methods of the second seed layer 126 and the second conductive structure 128 are similar to those of the first seed layer 120 and the first conductive structure 122 described in FIGS. 1F-1G, and their descriptions will not be repeated herein for brevity.

Referring to FIG. 1K, in some embodiments, the second seed layer 126 and/or a portion of the second conductive structure 128 on the second surface 102S2 of the substrate 102 are removed to expose the second surface 102S2. The second seed layer 126 and/or a portion of the second conductive structure 128 on the second surface 102S2 may be removed using a grinding method (e.g., using chemical mechanical polish (CMP), but the disclosure is not limited thereto, but the disclosure is not limited thereto.

Referring to FIG. 1L, in some embodiments, a first insulating layer 130 is formed on the second surface 102S2 of the substrate 102, covering the second conductive structure 128. In some embodiments, the materials of the first insulating layer 130 may include inorganic insulating materials, organic insulating materials, combinations thereof, or other suitable insulating materials, but the disclosure is not limited thereto. In accordance with some embodiments, inorganic materials may include silicon nitride, silicon oxide, silicon oxynitride, aluminum oxide, other suitable materials, or combinations thereof, but is not limited thereto. In accordance with some embodiments, organic materials may include epoxy resins, silicone resins, acrylic resins (e.g., polymethylmethacrylate (PMMA)), benzocyclobutene (BCB), polyimide, polyester, polydimethylsiloxane (PDMS), perfluoroalkoxy alkane (PFA), other suitable materials, or combinations thereof, but the disclosure is not limited thereto.

Referring to FIG. 1M, in some embodiments, after the formation of a second protective layer 132 on the second surface 102S2 of the substrate 102, the substrate 102 is flipped upside down (i.e., the first surface 102S1 facing upward). The second protective layer 132 may serve as a temporary protective film (TPF). In some embodiments, the second protective layer 132 may be removed, for example, in a subsequent manufacturing step of the electronic device 100 (as illustrated in the subsequent FIG. 1O), but the disclosure is not limited thereto. The materials used for the second protective layer 132 are similar to those of the first protective layer 124 described in FIG. 1H, and their descriptions will not be repeated herein for brevity. In some embodiments, a planarization process is performed to remove the first protective layer 124, the first seed layer 120 and/or the first conductive structure 122 on the first surface 102S1, thereby exposing the first surface 102S1 and/or the conductive pad layer 114. In some embodiments, the first conductive structure 122 and the second conductive structure 128 may be interconnected to form the connection structure 148.

Referring to FIG. 1N, in some embodiments, a first redistribution structure 134 is disposed or formed on the first surface 102S1 of the substrate 102. The first redistribution structure 134 includes a structure in which multiple circuit layers are sequentially stacked on the first surface 102S1. In some embodiments, the first redistribution structure 134 may include multiple alternately stacked insulating layers, first conductive layers 135, and conductive vias connecting the adjacent first conductive layers 135 to each other, but the disclosure is not limited thereto. In one embodiment, the first conductive layer 135 is formed on the first surface 102S1 of the substrate 102 and is electrically connected to the electronic component 112. In one embodiment, the electronic component 112 may be electrically connected to the connection structure 148 via the first conductive layer 135. In some embodiments, the material of the first conductive layer 135 may include metals or alloys, such as copper, but the disclosure is not limited thereto. The material of the above-mentioned insulating layer in the first redistribution structure 134 may include an elastic polymer. In some embodiments, the above-mentioned insulating layer in the first redistribution structure 134 may include photosensitive polyimide (PSPI), polyethylene (PE), polyethylene terephthalate (PET), polycarbonate (PC), polytetrafluoroethylene (PTFE), polystyrene (PS), acrylonitrile butadiene styrene copolymer (ABS), other suitable materials, or any combinations thereof, but the disclosure is not limited thereto.

Referring to FIG. 1O, in some embodiments, after the deposition or formation of a third protective layer 136 on the first redistribution structure 134 located on the first surface 102S1 of the substrate 102, the substrate 102 is flipped upside down (i.e., the second surface 102S2 facing upward). The third protective layer 136 may serve as a temporary protective film (TPF). In some embodiments, the third protective layer 136 may be removed, for example, in a subsequent manufacturing step of the electronic device 100 (as illustrated in the subsequent FIG. 1P), but the disclosure is not limited thereto. The materials used for the third protective layer 136 are similar to those of the first protective layer 124 described in FIG. 1H, and their descriptions will not be repeated herein for brevity.

In some embodiments, a second redistribution structure 138 is disposed or formed on the second surface 102S2 of the substrate 102. The second redistribution structure 138 includes a structure in which multiple circuit layers are sequentially stacked on the second surface 102S2. In some embodiments, the second redistribution structure 138 may include multiple alternately stacked insulating layers, second conductive layers 139, and conductive vias connecting the adjacent second conductive layers 139 to each other, but the disclosure is not limited thereto. In other words, the second conductive layer 139 is formed on the second surface 102S2 of the substrate 102. In one embodiment, the electronic component 112 is electrically connected to the second conductive layer 139 via the first conductive layer 135 and the connection structure 148. In some embodiments, the materials used for the second conductive layer 139 may include metals and alloys, such as copper (Cu), aluminum (Al), molybdenum (Mo), tungsten (W), gold (Au), chromium (Cr), nickel (Ni), platinum (Pt), titanium (Ti), silver (Ag), Tantalum (Ta), other suitable metal materials, or combinations thereof, but the disclosure is not limited thereto. The connection structure 148 may include seed layers, metals, or any combination thereof. In some embodiments, examples of the metals may include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials or any combination thereof, but the disclosure is not limited thereto.

Referring to FIG. 1P, in some embodiments, after flipping the substrate 102 upside down (i.e., the first surface 102S1 facing upward), the third protective layer 136 on the first surface 102S1 of the substrate 102 is removed. In some embodiments, an insulating layer 140 may be disposed onto the first redistribution structure 134 and/or the second redistribution structure 138. The insulating layer 140 may serve to shield the first redistribution structure 134 and/or the second redistribution structure 138 from moisture, for example, portions of the first conductive layer 135 and the second conductive layer 139 remain exposed as they are not covered by the insulating layer 140. In some embodiments, the materials of the insulating layer 140 may include moisture-resistant insulating materials, such as photoresist, solder resist, aluminum nitride (AlNx), silicon oxide (SiOx), or silicon nitride (SiNx), but the disclosure is not limited thereto. In some embodiments, the electronic component 142 is affixed to the first redistribution structure 134, thereby establishing electrical connectivity with the electronic component 112 through the first conductive layer 135. Specifically, the electronic component 142 may be electrically connected to the first conductive layer 135 via a bonding pad CP. Along the third direction Z (from a top view), the electronic component 142 may overlap with the first hole 104 and at least one second hole 106. Along the first direction X, the width of the electronic component 142 is greater than that of the electronic component 112. In some embodiments, the electronic component 142 and the electronic component 112 are, for example, different types of electronic components. The electronic component 142 may include passive components, active components, or combinations thereof, such as connectors, capacitors, resistors, inductors, varactor diodes, variable capacitors, filters, diodes, transistors, sensors, microelectromechanical system (MEMS) components, liquid crystal chips, etc., but the disclosure is not limited thereto. The diodes may include light emitting diodes or non-light emitting diodes. The diodes may include P-N junction diodes, PIN diodes or constant current diodes. The electronic component 142 may include dies or LED dies, which may be a die made of silicon (Si), gallium arsenide (GaAs), gallium nitride (GaN), silicon carbide (SiC), sapphire or a glass substrate, but the disclosure is not limited thereto. In another embodiment, the above-mentioned die may include a semiconductor packaging component, such as a ball grid array (BGA) packaging component, a chip size package (CSP) component, a flip-chip, or a 2.5D/3-dimensional (2.5D/3D) semiconductor packaging component, but the disclosure is not limited thereto. In another embodiment, the die may be any flip-chip bonding component, such as integrated circuits (ICs), transistors, controlled silicon rectifiers, valves, thin film transistors, capacitors, inductors, variable capacitors, filters, resistors, diodes, microelectromechanical system (MEMS) components, liquid crystal chips, etc., but the disclosure is not limited thereto.

Referring to FIG. 1Q, in some embodiments, a half-cutting process is performed to form a groove 143 along the edge of the electronic device 100. In some embodiments, the half-cutting process may include laser cutting process or wheel cutting process, but the disclosure is not limited thereto. The substrate 102 may be protected from being cut-off during the half-cutting process by adjusting the laser intensity in laser cutting or the cutting depth in wheel cutting.

In some embodiments, a filling layer 145 and/or an encapsulation layer 144 are formed over the electronic device 100. The encapsulation layer 144 may surround at least a portion of the side surface of the electronic component 142, but the disclosure is not limited thereto. In some embodiments, the encapsulation layer 144 may serve as structural support or reduce the impact of water and oxygen in the environment on the electronic component 142, but the disclosure is not limited thereto. In some embodiments, encapsulation layer 144 may be formed in the groove 143. In some embodiments, the encapsulation layer 144 may include an insulating material. The insulating material may include an organic insulating material. The organic insulating material may include epoxy, epoxy molding compound (EMC), Ajinomoto Build-up Film (ABF), polyimide (PI) or other suitable organic insulating materials, but the disclosure is not limited thereto. In some embodiments, the encapsulation layer 144 may formed over the electronic device 100 through thermal compression molding process, thermal injection molding process, vacuum lamination, deposition process, or other suitable processes, but the disclosure is not limited thereto.

Referring to FIG. 1R, in some embodiments, a solder structure 146 is formed on the exposed second conductive layer 139 and electrically contacts it. In some embodiments, a driving component (not shown) may be disposed on the side of the solder structure 146 away from the substrate 102. In some embodiments, the driving component may be, for example, an integrated circuit, a flexible printed circuit (FPC), a printed circuit board (PCB), a chip on board (COB), or a chip on film (COF), but the disclosure is not limited thereto. The material of the solder structure 146 may include solder and flux, but the disclosure is not limited thereto. In some embodiments, the composite stacked structure illustrated in FIG. 1Q is cut (e.g., using laser cutting) or singulated into individual electronic devices 100.

As illustrated in FIG. 1R, in one embodiment, an electronic device 100 includes a substrate 102, an electronic component 112, a connection structure 148 and a first conductive layer 135. The substrate 102 having a first hole 104 and a second hole 104. The electronic component 112 disposed in the first hole 104. The connection structure 148 disposed in the second hole 106. The first conductive layer 135 disposed on the first surface 102S1 of the substrate 102. In one embodiment, the electronic component 112 is electrically connected to the connection structure 148 via the first conductive layer 135. In one embodiment, the electronic device 100 further includes a second conductive layer 139, another electronic component 142, and a solder structure 146. The second conductive layer 139 disposed on a second surface 102S1 opposite to the first surface 102S1 of the substrate 102. The another electronic component 142 disposed on the side of the first conductive layer 135 away from the substrate 102 and electrically connected to the first conductive layer 135. The solder structure 146 disposed on the side of the second conductive layer 139 away from the substrate 102 and electrically connected to the second conductive layer 139.

In some embodiments, in a cross-sectional view, along the first direction X, the edge of the first redistribution structure 134 is at a first distance D1 (minimum distance) from the edge of the substrate 102, and the edge of the second redistribution structure 138 is at a second distance D2 (minimum distance) from the edge of the substrate 102. The first distance D1 may or may not be equal to the second distance D2. The warpage degree of the electronic device 100 can be adjusted according to the design of the first distance D1 and the second distance D2. In some embodiments, the first distance D1 may be greater than the second distance D2, but the disclosure is not limited thereto. In some embodiments, the groove 143 illustrated in FIG. 1Q forms the groove 150 after singulation. Because the encapsulation layer 144 is disposed in the groove 150, damage caused by external force impact on the edge of the substrate 102 can be reduced. In some embodiments, in a cross-sectional view, along the third direction Z, the groove 150 may have a depth D (maximum depth), and the substrate 102 may have a thickness T (the average thickness measured without holes as described above). The ratio of the depth D to the thickness T is less than 1 and greater than or equal to 0.1 (0.1≤D/T<1), for example, less than 1 and greater than or equal to 0.2 (0.2≤D/T<1) or less than 1 and greater than or equal to 0.5 (0.5≤D/T<1).

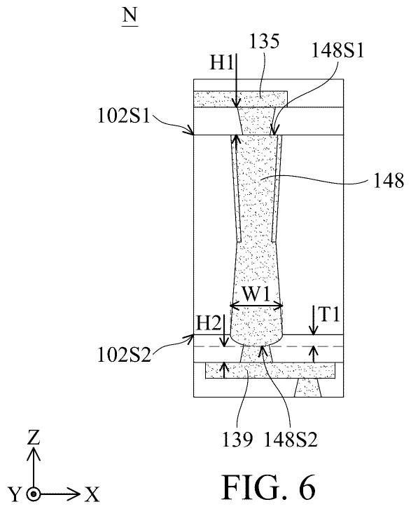

FIG. 6 is a magnified view of the connection structure 148 in a local area N of the electronic device 100 in FIG. 1R, in accordance with some embodiments. As illustrated in FIG. 6, in one embodiment, the connection structure 148 has a first plane 148S1 adjacent to the first surface 102S1 and a second plane 148S2 adjacent to the second surface 102S2. In one embodiment, the first plane 148S1 is a flat plane, and the second plane 148S2 is an arc plane (such as an outer convex arc surface), but the disclosure is not limited thereto.

In some embodiments, as illustrated in FIG. 6, the first surface 148S1 of the connection structure 148 may be substantially co-planar with the first surface 102S1 of the substrate 102, but the disclosure is not limited thereto. Advantageously, the first redistribution structure 134 located between the electronic component 142 and the first surface 148S1 of the connection structure 148 can be designed with thinner critical dimensions and/or higher alignment accuracy, but the disclosure is not limited thereto. In some embodiments, the second surface 148S2 of the connection structure 148 may protrude from the second surface 102S2, which can effectively reduce the impedance between the driving element (not shown; for example, electrically connected via the welding structure 146) and the second surface 148S2 of the connection structure 148, but the disclosure is not limited thereto. As illustrated in FIG. 6, in some embodiments, in the cross-sectional view of the electronic device 100, the second surface 148S2 has a protruding thickness T1 (along the third direction Z) relative to the second surface 102S2, while the second surface 102S2 has a width W1 (along the first direction X). The protruding thickness T1 and the width W1 satisfy the following equation: 0.05≤T1/W1≤0.3 or 0.1≤T1/W1≤0.25. When the protruding thickness T1 meets the above-mentioned conditions, the impedance can be appropriately reduced.

In some embodiments, in the cross-sectional view of the electronic device 100, along the third direction Z, the first surface 148S1 of the connection structure 148 and the first conductive layer 135 are separated by a third distance H1 (maximum distance). In some embodiments, in the cross-sectional view of the electronic device 100, along the third direction Z, the second surface 148S2 of the connection structure 148 and the second conductive layer 139 are separated by a fourth distance H2 (maximum distance). In some embodiments, the third distance H1 is greater than the fourth distance H2 (H1>H2), and the ratio of the third distance H1 to the fourth distance H2 may be greater than or equal to 1.3 and less than or equal to 3, but the disclosure is not limited thereto. In some embodiments, the ratio of the third distance H1 to the fourth distance H2 may be greater than or equal to 1.5 and less than or equal to 2.5, but the disclosure is not limited thereto.

In summary, the disclosure provides an electronic device a method of manufacturing the same. By employing the laser track pattern design rule of the disclosure during the laser process, holes with special shapes (e.g., rectangular, polygonal, etc.) can be formed in the substrate, in accordance with embodiments. In addition, through the dimension design of the laser track pattern, the profile of the holes at the corners can be made more symmetrical, or closer to a right angle. Furthermore, by designing the shape of the laser track pattern (e.g., arranging a series of laser tracks sequentially around each other or in a spiral shape), the required etching time in the subsequent etching process can be reduced (e.g., a shorter etching time), or relatively vertical sidewalls of holes can be obtained. In some embodiments of the disclosure, one side surface of the connection structure has a protruding surface, which can be appropriately reduced the impedance. Alternatively, in some embodiments, one side surface of the connection structure has a planar surface, which is conducive to the design of the subsequently formed redistribution structure with thinner critical dimensions and/or higher alignment accuracy.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of manufacturing an electronic device, comprising:
providing a substrate having a predetermined first hole region, a first surface, and a second surface opposite to the first surface;
laser processing the predetermined first hole region from the first surface to form a first laser track;
laser processing the predetermined first hole region from the first surface to form a second laser track, wherein the first laser track does not overlap the second laser track; and
etching the predetermined first hole region to form a first hole.

2. The method of claim 1, further comprising:
disposing an electronic component in the first hole; and
forming a first conductive layer on the first surface of the substrate, wherein the first conductive layer is electrically connected to the electronic component.

3. The method of claim 2, further comprising:
laser processing and etching a predetermined second hole region from the first surface to form a second hole;
forming a connection structure in the second hole; and
forming a second conductive layer on the second surface of the substrate, wherein the electronic component is electrically connected to the second conductive layer via the first conductive layer and the connection structure.

4. The method of claim 3, wherein etching the predetermined first hole region and etching the predetermined second hole region comprise performing an isotropic etching process to etch the predetermined first hole region and the predetermined second hole region simultaneously.

5. The method of claim 3, wherein the second hole has a top width Wt at the first surface, a bottom width Wb at the second surface, and a middle width Wm between the first surface and the second surface, and both the top width Wt and the bottom width Wb are greater than the middle width Wm.

6. The method of claim 1, wherein the first laser track surrounds the second laser track, the first laser track has a plurality of straight portions, adjacent ones of the straight portions are not parallel to each other and are spaced apart by a gap, and the second laser track has a plurality of portions, with one of the portions being adjacent to the gap.

7. The method of claim 6, wherein the adjacent ones of the straight portions are respectively a first portion and a second portion perpendicular to the first portion, the gap is between the first portion and the second portion, extension lines of the first and second portions intersect at a virtual point, wherein the virtual point is at a first shortest distance d1 from the first portion and at a second shortest distance d2 from the second portion, at least one of the first shortest distance d1 and the second shortest distance d2 is greater than zero (0), and a third shortest distance d3 between the virtual point and the one of the portions satisfies the following equation:
$$0 \text{.8} \times \sqrt{d {1}^{2} + d {2}^{2}} \leq d 3 \leq 1 \text{.2} \times \sqrt{d {1}^{2} + d {2}^{2}} .$$

8. The method of claim 7, wherein the first shortest distance d1 and the second shortest distance d2 satisfy the following equation:
$$0.8 \leq d 1 / d 2 \leq 1.2 .$$

9. The method of claim 6, wherein the portions of the second laser track are connected to each other.

10. The method of claim 9, wherein in a top view, the second laser track is spiral-shaped.

11. The method of claim 1, wherein laser processing the predetermined first hole region comprises modifying the predetermined first hole region.

12. The method of claim 1, further comprising:
laser processing the predetermined first hole region from the first surface to form a third laser track, wherein the third laser track is surrounded by the second laser track.

13. An electronic device, comprising:
a substrate having a first hole and a second hole;
an electronic component disposed in the first hole;
a connection structure disposed in the second hole; and
a first conductive layer disposed on the first surface of the substrate, wherein the electronic component is electrically connected to the connection structure via the first conductive layer, a top view profile of the first hole has a different shape from a top view profile of the second hole, and the top view profile of the first hole comprises a plurality of straight sides, with adjacent ones of the straight sides connected by an arc side.

14. The electronic device of claim 13, wherein extension lines of the adjacent ones of straight sides of the top view profile of the first hole intersect at a virtual point, the virtual point is spaced apart from the arc side by a shortest distance d, and a maximum width w of the first hole and the shortest distance d satisfy the following equation:
$$0 < d / w \leq 0.1 .$$

15. The electronic device of claim 13, wherein in a cross-sectional view of the electronic device, the substrate has a thickness T, a side surface of the second hole is an arc plane with a radius of curvature a, and the thickness T and the radius of curvature a satisfy the following equation:
$$T / 2 < a \leq 10 T .$$

16. The electronic device of claim 13, further comprising:
a second conductive layer disposed on a second surface opposite to the first surface of the substrate;
another electronic component disposed on a side of the first conductive layer away from the substrate and electrically connected to the first conductive layer; and
a solder structure disposed on a side of the second conductive layer away from the substrate and electrically connected to the second conductive layer, wherein the connection structure has a first plane that is a flat plane adjacent to the first surface and a second plane that is an arc plane adjacent to the second surface.

17. The electronic device of claim 16, wherein in a cross-sectional view of the electronic device, the second plane has a protruding thickness T1 relative to the second surface and has a width W1, and the protruding thickness T1 and the width W1 satisfy the following equation:
$$0.05 \leq T 1 / W 1 \leq 0 \text{.3} .$$

18. The electronic device of claim 13, wherein the first hole is a blind hole and the second hole is a through hole.

19. The electronic device of claim 13, wherein the top view profile of the first hole is approximately rectangular, and the top view profile of the second hole is approximately circular.

20. The electronic device of claim 13, wherein in a cross-sectional view of the electronic device, the substrate has a thickness T, a groove at an edge of the electronic device has a depth D, and the thickness T and the depth D satisfy the following equation:
$$0.1 \leq D / T < 1 .$$
